(19) United States
(12) Patent Application Publication
(10) Pub. No.: US 2007/0148929 A1
(43) Pub. Date: Jun. 28, 2007

(54) Method for Manufacturing CMOS Image Sensor

(76) Inventor: Sang Gi Lee, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/614,097

(22) Filed: Dec. 21, 2006

(30) Foreign Application Priority Data
Dec. 28, 2005 (KR) 10-2005-0132099

(51) Int. Cl. H01L 21/425

(52) U.S. Cl. 438/527

(57) ABSTRACT

A method of manufacturing a CMOS (complementary metal oxide semiconductor) image sensor is provided. The method can include: providing a semiconductor substrate having a PMOS region, and a photodiode region; forming a gate on the semiconductor substrate; implanting a low concentration of n-type impurities only in the NMOS region to form an n-type LDD region; implanting impurities only in the photodiode region; implanting impurities only in a region between the photodiode region and a device isolation layer formed on the substrate; implanting a high concentration of p-type impurities only in the PMOS region to form a p-type LDD region; forming spacers at sidewalls of the gate; implanting a high concentration of n-type impurities only in the NMOS region to form n-type source/drain regions; and implanting a high concentration of p-type impurities only in the PMOS region to form p-type source/drain regions.

### RELATED APPLICATION

This application claims the benefit under 35 U.S.C. §119(e), of Korean Patent Application Number 10-2005-0132099 filed Dec. 28, 2005, which is incorporated herein by reference in its entirety.

### FIELD OF THE INVENTION

The present invention relates to a method for manufacturing an image sensor.

### BACKGROUND OF THE INVENTION

In general, an image sensor is a semiconductor device that transforms an optical image to electrical signals. The image sensor is generally classified as a charge coupled device (CCD) or a complementary metal oxide semiconductor (CMOS) image sensor.

However, the CCD is disadvantageous in that it has a complicated driving method, exhibits high power consumption, and is produced via a complicated fabrication process involving multiple photo process stages. Recently, the CMOS sensor has been heralded as the next generation image sensor that can overcome the disadvantages of CCDs.

That is, the CMOS image sensor has a photodiode and a MOS transistor formed within each unit pixel. By monitoring the switching of the MOS transistors, the CMOS image sensor successively detects electric signals from the photodiodes of the unit pixels to reproduce an image.

The photodiode and MOS transistors are formed in an active region of a substrate defined by a device isolation layer. The device isolation layer functions to isolate adjacent active regions. In a method for manufacturing the CMOS image sensor according to the related art, in order to prevent a blue photodiode from coming into contact with a device isolation layer, after an etching of the device isolation area, an ion (such as boron B) implantation process is further performed at the edge region between the silicon substrate and the device isolation layer.

However, in the method for manufacturing the CMOS image sensor according to the related art, in order to implant the boron at the isolation layer-photodiode edge region, an impurity ion implantation process using an additional photoresist pattern as a mask is further performed. Accordingly, the process becomes complicated.

Moreover, in the related art, through a subsequent thermal treatment process, boron B can be diffused outside the desired region. Due to this, it is difficult to improve a current loss occurring from an edge region of the device isolation layer.

### BRIEF SUMMARY

Accordingly, embodiments of the present invention are directed to a method for manufacturing a CMOS image sensor that substantially obviates one or more problems due to limitations and disadvantages of the related art.

An object of the present invention is to provide a method for manufacturing a CMOS image sensor, capable of improving a current loss characteristic of a photodiode of a vertical CMOS image sensor.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method of manufacturing a CMOS (complementary metal oxide semiconductor) image sensor comprising: providing a semiconductor substrate, which is divided into a PMOS region, an NMOS region, and a photodiode region; forming a device isolation layer on the semiconductor substrate; forming a gate on the semiconductor substrate; exposing the NMOS region and implanting a low concentration of n-type impurities in the exposed NMOS region to form an n-type LDD region; exposing the photodiode region and implanting impurities in the exposed photodiode region; exposing a region between the photodiode region and the device isolation layer and implanting impurities in the exposed region; exposing the PMOS region and implanting a high concentration of p-type impurities in the open PMOS region to form a p-type LDD region; forming spacers at the gate sidewalls; exposing the NMOS region and implanting a high concentration of n-type impurities in the exposed NMOS region to form n-type source/drain regions; and exposing the PMOS region and implanting a high concentration of p-type impurities in the exposed PMOS region to form p-type source/drain regions.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 to 7 are cross-sectional views for describing a method for manufacturing the CMOS image sensor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

The following is the method for manufacturing the CMOS image sensor according to an embodiment of the present invention with reference to the accompanying drawings.

In the description of an embodiment of the present invention, when something is formed “on” each layer, the “on” includes the concepts of “directly and indirectly”.

FIGS. 1 to 7 are cross-sectional views of the CMOS image sensor for describing a method for manufacturing the CMOS image sensor according to an embodiment of the present invention.

Referring to FIG. 1, impurity ions can be selectively implanted in a semiconductor substrate 231 to sequentially form a red R-photodiode 281 and a green G-photodiode 282 for sensing red R and green G signals. The R-photodiode 281 and G-photodiode can be formed to have different depths at a photodiode region.

Next, in order to isolate a pixel region from a peripheral circuit region, using a hard mask (not shown) such as a nitride layer, a predetermined part of the semiconductor 231 can be amorphously etched to form a trench. Further, an oxide layer can be deposited to fill the trench. Moreover, a chemical mechanical polishing (CMP) process planarizes a surface of the resulting object to complete the formation of a shallow trench isolation (STI) 232.

Then, an n-type well region 251 can be formed at a region in which a PMOS transistor will be formed on the semiconductor substrate 231. An oxide layer and a polysilicon layer can be sequentially deposited on the semiconductor substrate 231, and can be patterned using a gate mask to form a gate oxide layer 241 and a gate 242 for an NMOS transistor and a PMOS transistor.

In one embodiment, a single layer of a polysilicon can form the gate. However, a metal may further be formed on an upper portion of the polysilicon for improved resistivity. A diffusion prevention layer, a laminate layer of tungsten, and a silicide tungsten can be used as the metal formed on the polysilicon.

Then, referring to FIG. 2, in order to expose only the NMOS transistor region, a first photoresist pattern 291 can be formed on the substrate to only expose the NMOS transistor region. Then, a low concentration of n-type impurity ions can be implanted using the first photoresist pattern 291 as a mask to form an n-type LDD region 243 at the NMOS transistor region.

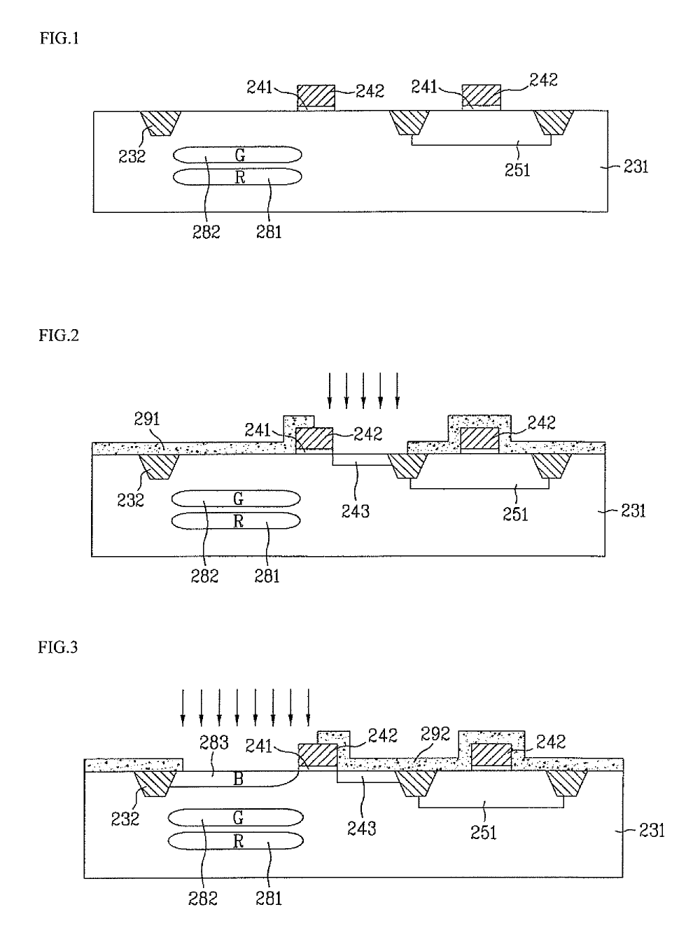

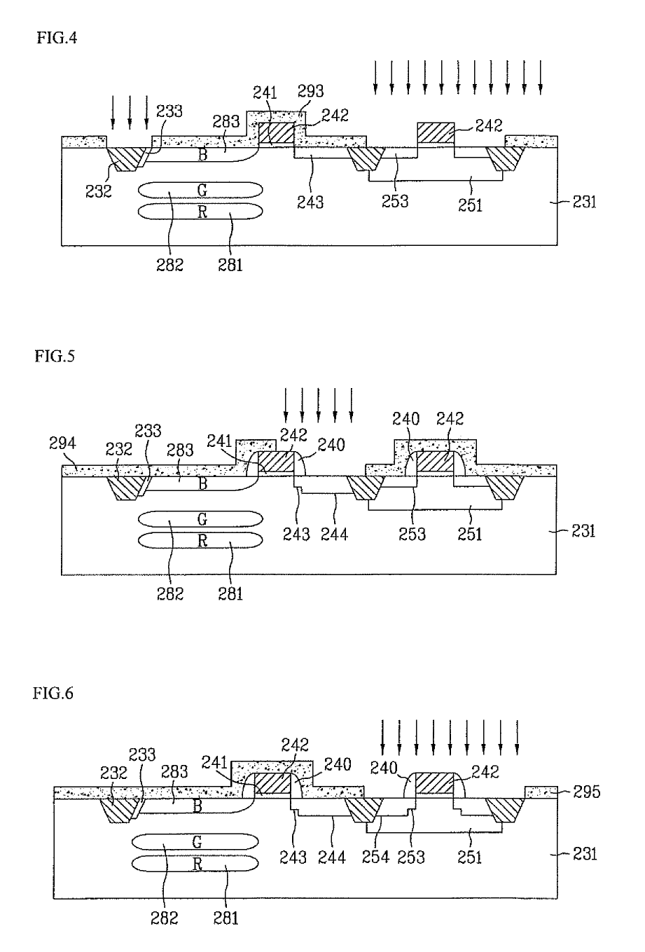

Next, referring to FIG. 3, a second photoresist pattern 292 can be formed on the substrate exposing only the photodiode regions. Then, n-type impurity ions, such as arsenic As, can be implanted in the substrate to form a blue B-photodiode 283 for sensing blue B signals.

Then, referring to FIG. 4, a third photoresist pattern 293 can be formed on the substrate to expose the PMOS transistor region and an edge region between an isolation layer 232 and the B-photodiode. Then, a low concentration of p-type impurity ions can be implanted therein to form a p-type LDD region 253 at the PMOS transistor region and to form a sidewall 233 at the edge region of the B-photodiode.

As described above, impurity ions can be implanted into the edge of the B-photodiode, namely, an edge region of a device isolation layer 232 as well as the LDD region of the PMOS transistor. Here, p-type ions are implanted in the p-type LDD region. Simultaneously, ions can be implanted in the edge region of the B-photodiode 283.

Since the sidewall 223 formed of a p-type impurity ion encloses the edge region of the B-photodiode, the loss characteristic of an electric current induced from the device isolation layer can be improved. Further, the current loss may be significantly enhanced by suitably adjusting a dose of ions and an energy applied to the LDD region of the PMOS transistor. In particular, because the PMOS transistor is used at a peripheral circuit, a performance can be adjusted by a little change of an LDD implant. Moreover, including an opening portion of an edge region in a photoresist pattern for an LDD implant allows an edge region of a B-photodiode to be freely adjusted, thereby enhancing a performance.

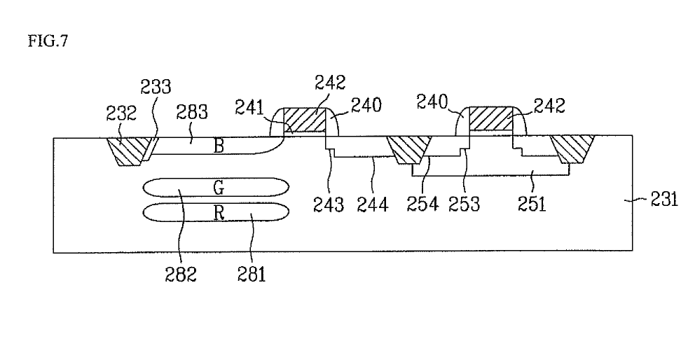

Next, referring to FIG. 5, an oxide layer can be deposited on an entire surface of a semiconductor substrate 231, and a blanket etch back process can be performed to form a spacer 240 on a sidewall of a gate 242.

Subsequently, a fourth photoresist pattern can be formed on the substrate to expose only the NMOS transistor region. Then, n-type impurity ions such as arsenic As can be implanted therein to form n-type source/drain regions 244.

Next, referring to FIG. 6, the fourth photoresist pattern 294 can be removed. Then, a fifth photoresist pattern 295 can be formed to expose only the PMOS transistor region, and p-type impurity ions such as boron B can be implanted therein to form p-type source/drain region 254. The impurity ions can be implanted at high concentration in the PMOS transistor region.

In another embodiment, the fifth photoresist pattern 295 can expose the PMOS transistor region and an edge of the B-photodiode, such that implanting a high concentration of p-type impurity ions therein forms p-type source/drain regions 254 at a PMOS transistor region and simultaneously forms a sidewall 233 at the edge region of the B-photodiode.

That is, in one embodiment the sidewalls 233 can be formed during a formation process of the p-type LDD region. However, in another embodiment, the sidewalls 233 can be formed during a formation process of the p-type source/drain regions. In a further embodiment, both implantations can be performed.

Accordingly, when the fifth photoresist pattern 295 is removed, as shown in FIG. 7, a B-photodiode 283 can be completed, which is spaced apart from the device isolation layer 232 by the sidewall 233.

Moreover, although it is not shown, an interlayer dielectric can be formed on an entire surface of the semiconductor substrate including the gate. Then, a transistor can be completed by forming source/drain electrodes contacting source/drain regions through contacts formed in the interlayer dielectric. Then, when a logic structure is finished through a subsequent wiring process, a CMOS image sensor can be finally completed.

The method for manufacturing a CMOS image sensor according to embodiments of the present invention as described above has the following effects.

First, in the present invention, after a B-photodiode has been formed in the vertical CMOS image sensor, impurity ions can be implanted in an open region between the B-photodiode and a device isolation layer during a formation of a p-type LDD region. Alternatively, ions can be implanted in the edge region during formation of p-type source/drain regions. Accordingly, the impurity ions can be implanted in an edge part of the B-photodiode without an extra mask pattern. As a result, the present invention may form a sidewall at an edge region of a B-photodiode simpler in comparison with a process according to the related art.

Second, in the present invention, the simple process as described above can isolate the B-photodiode from the device isolation layer, and freely implant impurity ions in the edge region of the B-photodiode, thereby enhancing a loss characteristic of an electric current induced from the device isolation layer.

Third, in the present invention, since impurity ions are implanted in a p-type LDD region during the latter half of a fabrication process, a diffusion problem of impurity ions caused by multiple heating processes can be solved. Further, a further implantation of impurity ions for forming a sidewall is not necessary.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method of manufacturing a CMOS (complementary metal oxide semiconductor) image sensor comprising:
forming a device isolation layer on the semiconductor substrate defining a PMOS region, an NMOS region and a photodiode region;
forming a gate on the NMOS region and PMOS region of the semiconductor substrate;
implanting a low concentration of n-type impurities in the NMOS region to form an n-type LDD region;
implanting impurities in the photodiode region;
implanting impurities in a region between the photodiode region and the device isolation layer after implanting impurities in the photodiode region;
implanting a high concentration of p-type impurities in the PMOS region to form a p-type LDD region;
forming spacers on sidewalls of the gate;
implanting a high concentration of n-type impurities in the NMOS region to form n-type source/drain regions; and
implanting a high concentration of p-type impurities in the PMOS region to form p-type source/drain regions.

2. The method according to claim 1, wherein implanting impurities in the region between the photodiode region and the device isolation layer and implanting a high concentration of p-type impurities in the PMOS region to form a p-type LDD region are simultaneously performed.

3. The method according to claim 1, wherein implanting impurities in the region between the photodiode region and the device isolation layer and implanting a high concentration of p-type impurities in the PMOS region to form p-type source/drain regions are simultaneously performed.

4. The method according to claim 1, wherein implanting impurities in the photodiode region comprises implanting n-type impurities in the photodiode region.

5. The method according to claim 4, wherein the n-type impurities are arsenic (As).

6. The method according to claim 1, wherein the n-type impurities are arsenic (A)s.

7. The method according to claim 1, wherein the p-type impurities are boron (B).

8. The method according to claim 1, wherein implanting impurities in the photodiode region forms a B-photodiode.

9. The method according to claim 8, further comprising forming an R-photodiode and a G-photodiode at the photodiode region prior forming the device isolation layer on the semiconductor substrate.

10. The method according to claim 9, wherein the R-photodiode, the G-photodiode, and the B-photodiode vertically overlap with each other.

11. The method according to claim 1, wherein implanting impurities in the region between the photodiode region and the device isolation layer forms a sidewall at a B-photodiode edge region.

12. The method according to claim 1, further comprising forming an n-well region at the PMOS region prior to forming the gate on the semiconductor substrate.

13. The method according to claim 1, further comprising forming a gate oxide layer below the gate.
